(19) United States
(12) Patent Application Publication
(10) Pub. No.: US 2006/0105200 A1
(43) Pub. Date: May 18, 2006

(54) Organic electroluminescent device

(76) Inventors: Dmytro Poplavskyy, San Jose, CA (US); Reza Stegamat, Milpitas, CA (US); Florian Pschenitzka, San Jose, CA (US)

Correspondence Address: EPPING, HERMANN, FISCHER, Ridlerstrasse 55, Munich, 80339, DE

(21) Appl. No.: 10/992,037

(22) Filed: Nov. 17, 2004

(51) Int. Cl. H01L 51/54; H05B 33/14

(52) U.S. Cl. 428/690; 428/917; 313/504; 313/506; 257/E51.039; 257/E51.04

(57) ABSTRACT

An electroluminescent device has a hole transporting interlayer which incorporates nanostructures, including carbon nanostructures. In some embodiments, other layers such as the emissive layer of the device can also incorporate nanostructures therein.

### BACKGROUND

A typical structure of an organic electroluminescent device consists of an anode (e.g. indium-tin-oxide (ITO)), a hole injection layer (e.g. PEDOT:PSS or polyaniline), a hole transport layer (e.g. an amine-based organic material), an electroluminescent layer, and a cathode layer (e.g. barium covered with aluminum). The function of the hole injection layer is to provide efficient hole injection into subsequent layers. In addition, hole injection layer also acts as a buffer layer to smooth the surface of the anode and to provide a better adhesion for the subsequent layer. The function of the hole transport interlayer is to transport holes, injected from the hole injection layer, to the electroluminescent layer, where recombination with electrons will occur and light will be emitted. This layer usually consists of a high hole mobility organic material, such as TPD, NPD, amine-based starburst compounds, amine-based spiro-compounds and so on. Another function of the hole transporting interlayer is to move the recombination zone away from the interface with the hole injection layer. The function of the electroluminescent layer is to transport both types of carriers and to efficiently produce light of desirable wavelength from electron-hole pair (exciton) recombination. The function of the electron injection layer is to efficiently inject electrons into the electroluminescent layer.

Relatively low operational lifetimes of organic light-emitting devices, such as polymer light-emitting diodes (PLEDs) or small-molecule light-emitting diodes (SMOLEDs), are a serious problem on the way to wide-scale commercialization of organic electroluminescent devices. Many factors are responsible for limited operational lifetime of such devices, some of which, but not all, include degradation of injecting electrodes, degradation of light-emitting properties of the emitting material, deterioration of charge transporting properties of materials, that constitute a device, and many others.

One of the approaches to increase life-time of organic electroluminescent devices concentrates on the device architecture, i.e. modifying device structure to include additional functional layers, such as an electron blocking layer, hole transporting layer, an electron transporting layer, and so on. Another approach is to design material(s) that will be stable under given operational conditions in a given device architecture. For example, electron traps can be added to the emitting material in order to balance electron and hole currents in order to have a more stable device operation. Other approaches include chemical modification of the materials, that constitute a device, e.g. to prevent aggregation and crystallization, to provide better quality interfaces and so on.

In other known approaches, nanostructures are added only in emissive layers formed from PPV (poly(p-phenylene vinylene)) conjugated polymers by blending a PPV with nanostructures to one without nanostructures. This is disclosed in a U.S. Patent Application publication No. 2004/0150328 having a serial number of 10/356,702. However, this method is quite narrow and restrictive in use.

There is a need for a more flexible approach to increasing operational lifetime of EL devices.

### BRIEF DESCRIPTION OF THE DRAWINGS

FIG. 1 shows a cross-sectional view of an embodiment of an EL device 405 according to at least one embodiment of the invention.

FIG. 2 shows a cross-sectional view of an embodiment of an EL device 505 according to at least a second embodiment of the invention.

FIG. 3 illustrates an exemplary nanostructure utilized in one or more embodiments of the invention.

FIG. 4 shows a cross-sectional view of an embodiment of an EL device 605 according to at least a second embodiment of the invention.

### DETAILED DESCRIPTION

In at least one embodiment of the invention, an EL device structure is disclosed which combines the use of a hole transporting (HT) interlayer and carbon nanostructures in the HT interlayer as well as in other layers. The introduction of nanostructures into one or more layers of the EL device improves its operating lifetime. The nanostructures may include one or more of the following: fullerene (including C60, C70, C76, C78, C82, C84, C90, C96, C140 and so on), soluble fullerene derivatives (including corresponding soluble derivatives of C60, C70, C76, C78, C82, C84, C90, C96, C140 and so on), carbon nanotubes (both single-wall and multi-wall nanotubes). The nanostructures may also include porphyrines, metal filled nanotubes, boron nitride nanotubes, other non-carbon nanotubes or nanostructures and carbon nanotubes doped with boron, nitrogen and so on. Carbon nanostructures are added to layers which have an emissive function such as the light-emitting polymer (LEP) (or electroluminescent small molecule) layer and/or other layers such as the hole transporting interlayer which do not have an emissive function.

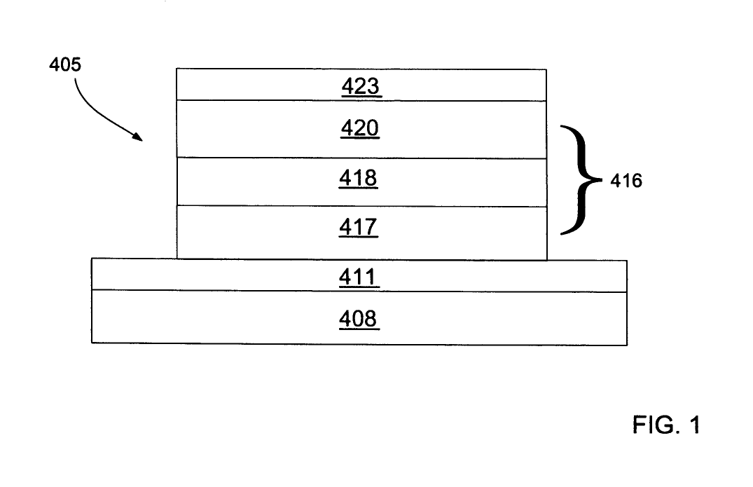

In one embodiment of the invention (e.g. FIG. 1), carbon nanostructures are added to the hole transporting interlayer (HT interlayer) 418 of the EL device. Apart from the hole transport function, the HT interlayer may also serve an emissive function as well. The concentration of nanostructures used in the HT interlayer should be in the range between about 0 and 20 percent by weight if the HT interlayer does not emit light and in the range between 0 and 1% if the HT interlayer also produces significant light output supplemental to the emission from the emissive layer (EML). A lower concentration should be used in the latter case due to possible quenching effect of carbon nanostructures on luminescence efficiency of the emitting component of the HT interlayer. In other embodiments of the invention, an EL device structure is disclosed which combines the use of a hole transporting (HT) interlayer not doped with carbon nanostructures and an EML doped with carbon nanostructures.

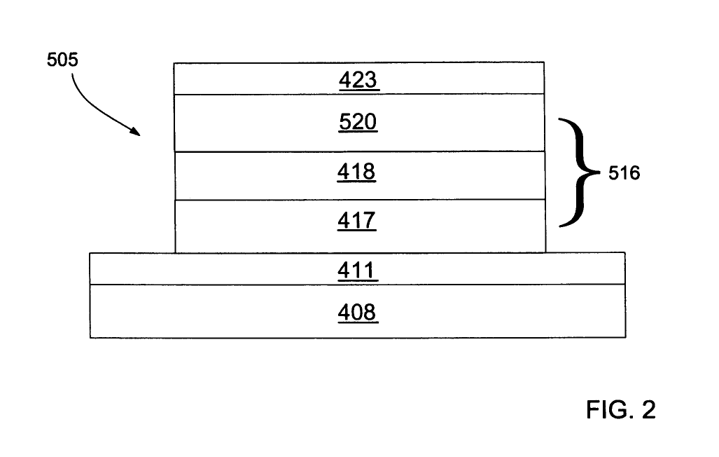

In at least one embodiment of the invention, carbon nanostructures are added both to the hole transport and emissive layers, as shown in FIG. 2. Concentration of nanostructures in the EML should be low enough to prevent emission quenching due to the presence of nanostructures, and should lie in the range between 0 and 1 percent by weight. The concentration of nanostructures in the HT interlayer is same as in the previous embodiment, shown in FIG. 1.

Incorporation of carbon nanostructures into the functional layers can be done in a variety of ways that include one or more of: 1) blending nanostructures with the functional organic material; 2) chemically attaching or cross-linking carbon nanostructures to the functional organic material, e.g. as a part of the chain in the copolymer structure or as a pendant group; and/or 3) co-evaporation of carbon nanostructures with the functional organic small molecule materials. A layer consisting only of carbon nanostructures can also be evaporated to form an additional functional layer, e.g. a hole blocking layer.

The use of nanostructures, in accordance with the invention, is not limited to any particular type of organic materials and can be used with the fluorescent and phosphorescent conjugated polymers, or with the fluorescent and phosphorescent small molecule materials. Examples of small molecule materials include triphenyldiamine (TPD), α-napthylphenyl-biphenyl (NPB), tris(8-hydroxyquinolate) aluminum (Alq₃), tris(2-phenylpyridine) iridium (Ir(ppy)₃), and so on, examples of polymers include PPV, MEH-PPV, polyfluorene homopolymer and copolymers, spiro-based polymers and so on.

The concentration of nanostructures incorporated into the layers depends upon the following factors:
1) whether the layer is intended for light emission or consequentially has a light emitting component, i.e. the light emission, if desirable, should not be quenched significantly, and;
2) the type of nanostructure used and the composition of other materials used to form the layer,; and
3) the desired output spectrum from the EL device.

FIG. 1 shows a cross-sectional view of an embodiment of an EL device 405 according to at least one embodiment of the invention. The EL device 405 may represent one pixel or sub-pixel of a larger display. As shown in FIG. 1, the EL device 405 includes a first electrode 411 on a substrate 408. As used within the specification and the claims, the term “on” includes when layers are in physical contact or when layers are separated by one or more intervening layers. The first electrode 411 may be patterned for pixilated applications or remain un-patterned for backlight applications.

One or more organic materials are deposited to form one or more organic layers of an organic stack 416. The organic stack 416 is on the first electrode 411. The organic stack 416 includes a hole injection/anode buffer layer (“HIL/ABL”) 417 and emissive layer (EML) 420 and a hole transporting (HT) interlayer 418 disposed between the HIL/ABL 417 and the EML layer 420. If the first electrode 411 is an anode, then the HIL/ABL 417 is on the first electrode 411. Alternatively, if the first electrode 411 is a cathode, then the active electronic layer 420 is on the first electrode 411, and the HIL/ABL 417 is on the EML 420. The OLED device 405 also includes a second electrode 423 on the organic stack 416. Other layers than that shown in FIG. 1 may also be added including barrier, charge transport/injection, and interface layers between or among any of the existing layers as desired. Some of these layers, in accordance with the invention, are described in greater detail below.

Substrate 408

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of an active-matrix OLED device. A single substrate 408 is typically used to construct a larger display containing many pixels (EL devices) such as EL device 405 repetitively fabricated and arranged in some specific pattern.

First Electrode 411

In one configuration, the first electrode 411 functions as an anode (the anode is a conductive layer which serves as a hole-injecting layer and which comprises a material with work function typically greater than about 4.5 eV). Typical anode materials include metals (such as platinum, gold, palladium, and the like); metal oxides (such as lead oxide, tin oxide, ITO (Indium Tin Oxide), and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device. The thickness of the first electrode 411 can be from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”.

HIL/ABL 417

The HIL/ABL 417 has good hole conducting properties and is used to effectively inject holes from the first electrode 411 to the EML 420 (via the HT interlayer 418, see below). The HIL/ABL 417 is made of polymers or small molecule materials. For example, the HIL/ABL 417 can be made of tertiary amine or carbazole derivatives both in their small molecule or their polymer form, conducting polyaniline (“PANI”), or PEDOT:PSS (a solution of poly(3,4-ethylenedioxythiophene) (“PEDOT”) and polystyrenesulfonic acid (“PSS”) available as Baytron P from HC Starck). The HIL/ABL 417 can have a thickness from about 5 nm to about 1000 nm, and is conventionally used from about 50 to about 250 nm.

Other examples of the HIL/ABL 417 include any small molecule materials and the like such as plasma polymerized fluorocarbon films (CFx) with preferred thicknesses between 0.3 and 3 nm, copper phthalocyanine (CuPc) films with preferred thicknesses between 10 and 50 nm.

The HIL/ABL 417 can be formed using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. A hole transporting and/or buffer material is deposited on the first electrode 411 and then allowed to dry into a film. The dried film represents the HIL/ABL 417. Other deposition methods for the HIL/ABL 417 include plasma polymerization (for CFx layers), vacuum deposition, or vapour phase deposition (e.g. for films of CuPc).

HT Interlayer 418

The functions of the HT interlayer 418 are among the following: to assist injection of holes into the EML 420, reduce exciton quenching at the anode, provide better hole transport than electron transport, and block electrons from getting into the HIL/ABL 417 and degrading it. Some materials may have one or two of the desired properties listed, but the effectiveness of the material as an interlayer is believed to improve with the number of these properties exhibited. Through careful selection of the materials, an efficient interlayer material can be found. Examples of criteria that can be used are as follows: a criterion that can be used to find materials that can help injection of holes into the EML 420 is that the HOMO (Highest Occupied Molecular Orbital) levels of the material bridge the energy barrier between the anode and the EML 420, that is the HOMO level of the HT interlayer 418 should be in between the HOMO levels of the anode and the EML 420. Charge carrier mobilities of the materials can be used as a criterion to distinguish materials that will have better hole transport than electron transport. Also, materials that have higher LUMO (Lowest Unoccupied Molecular Orbital) levels than the LUMO of the EML 420 will present a barrier to electron injection from the EML 420 into the HT interlayer 418, and thus act as an electron blocker. The HT interlayer 418 may consist at least partially of or may derive from one or more following compounds, their derivatives, moieties, etc: polyfluorene derivatives, poly(2,7-(9,9-di-n-octylfluorene)-(1,4-phenylene-((4-secbutylphenyl)imino)-1,4-phenylene) and derivatives which include cross-linkable forms, non-emitting forms of poly(p-phenylenevinylene), triarylamine type material (e.g. triphenyldiamine (TPD), α-napthylphenyl-biphenyl (NPB)), thiopene, oxetane-functionalized polymers and small molecules etc. In some embodiments of the invention, the HT interlayer 418 is fabricated using a cross-linkable hole transporting polymer.

In accordance with at least one embodiment of the invention, nanostructures are incorporated into a HT (hole transporting) interlayer 418 provided between HIL/ABL 417 and EML 420. For example, the nanostructures may include one or more of the following: fullerene (including C60, C70, C76, C78, C82, C84, C90, C96, C140 and so on), soluble fullerene derivatives (including corresponding soluble derivatives of C60, C70, C76, C78, C82, C84, C90, C96, C140 and so on), carbon nanotubes (both single-wall and multi-wall nanotubes). The nanostructures may also include porphyrines, metal filled nanotubes, boron nitride nanotubes, other non-carbon nanotubes or nanostructures and carbon nanotubes doped with boron, nitrogen and so on. Some embodiments of the invention utilize for the nanostructures a soluble derivative of fullerene, namely phenyl-C61-butyric-acid-methyl-ester (PCBM) which is blended with the hole transporting polymer material to form HT interlayer 418.

The concentration of nanostructures used in the HT interlayer should be in the range between 0 and 20 percent by weight if the HT interlayer 418 does not emit light and in the range between 0 and 1% if the HT interlayer also produces significant light output supplemental to the emission from EML 420.

The HT interlayer 418 can be ink-jet printed by depositing an organic solution, by spin-coating, by vacuum deposition, by vapor phase deposition, or other deposition techniques.

Further, if required, the HT interlayer 418 may be cross-linked or otherwise physically or chemically hardened as desired for stability and maintenance of certain surface properties desirable for deposition of subsequent layers.

EML 420

For organic LEDs (OLEDs), the EML 420 contains at least one organic material that emits light. These organic light emitting materials generally fall into two categories. The first category of OLEDs, referred to as polymeric light emitting diodes, or PLEDs, utilize polymers as part of EML 420. The polymers may be organic or organo-metallic in nature. As used herein, the term organic also includes organo-metallic materials. Light-emission in these materials may be generated as a result of fluorescence or phosphorescence.

Preferably, these polymers are solvated in an organic solvent, such as toluene or xylene, and spun (spin-coated) onto the device, although other deposition methods are possible too. Devices utilizing polymeric active electronic materials in EML 420 are especially preferred.

The light emitting organic polymers in the EML 420 can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, organic polymers can be, for example: polyfluorenes; poly-p-phenylenevinylenes that emit white, red, blue, yellow, or green light and are 2-, or 2,5-substituted poly-p-pheneylenevinylenes; polyspiro polymers.

In addition to polymers, smaller organic molecules that emit by fluorescence or by phosphorescence can serve as a light emitting material residing in EML 420. Unlike polymeric materials that are applied as solutions or suspensions, small-molecule light emitting materials are preferably deposited through evaporative, sublimation, or organic vapor phase deposition methods. There are also small molecule materials that can be applied by solution methods too. Combinations of PLED materials and smaller organic molecules can also serve as active electronic layer. For example, a PLED may be chemically derivatized with a small organic molecule or simply mixed with a small organic molecule to form EML 420. Examples of electroluminescent small molecule materials include tris(8-hydroxyquinolate) aluminum (Alq₃), anthracene, rubrene, tris(2-phenylpyridine) iridium (Ir(ppy)₃), triazine, any metal-chelate compounds and derivatives of any of these materials.

In addition to active electronic materials that emit light, EML 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, triphenylamine, and triphenyldiamine. EML 420 may also include semiconductors, such as silicon, gallium arsenide, cadmium selenide, or cadmium sulfide. In accordance with some embodiments of the invention described in FIG. 1, the EML 420 does not have any carbon nanostructures added to it.

All of the organic layers such as HIL/ABL 417, HT interlayer 418 and EML 420 can be ink-jet printed by depositing an organic solution or by spin-coating, or other deposition techniques. This organic solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops.

For instance, the HT interlayer 418 can be fabricated by depositing this solution, using either a selective or non-selective deposition technique, onto HIL/ABL 417. Further, any or all of the layers 417, 418 and 420 may be cross-linked or otherwise physically or chemically hardened as desired for stability and maintenance of certain surface properties desirable for deposition of subsequent layers.

Alternatively, if small molecule materials are used instead of polymers, the HIL/ABL 417, the HT interlayer 418, the EML 420 can be deposited through evaporation, sublimation, organic vapor phase deposition, or in combination with other deposition techniques.

Second Electrode (423)

In one embodiment, second electrode 423 functions as a cathode when an electric potential is applied across the first electrode 411 and the second electrode 423. In this embodiment, when an electric potential is applied across the first electrode 411, which serves as the anode, and second electrode 423, which serves as the cathode, photons are released from active electronic layer 420 and pass through first electrode 411 and substrate 408.

While many materials, which can function as a cathode, are known to those of skill in the art, most preferably a composition that includes aluminum, indium, silver, gold, magnesium, calcium, lithium fluoride, cesium fluoride, sodium fluoride, and barium, or combinations thereof, or alloys thereof, is utilized. Aluminum, aluminum alloys, and combinations of magnesium and silver or their alloys can also be utilized. In some embodiments of the invention, a second electrode 423 is fabricated by thermally evaporating in a three layer or combined fashion lithium fluoride, calcium and aluminum in various amounts.

Preferably, the total thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred.

Often other steps such as washing and neutralization of films, addition of masks and photo-resists may precede cathode deposition. However, these are not specifically enumerated as they do not relate specifically to the novel aspects of the invention. Other steps (not shown) like adding metal lines to connect the anode lines to power sources may also be included in the workflow. Other layers (not shown) such as a barrier layer and/or getter layer and/or other encapsulation scheme may also be used to protect the electronic device. Such other processing steps and layers are well-known in the art and are not specifically discussed herein.

FIG. 2 shows a cross-sectional view of an embodiment of an EL device 505 according to at least a second embodiment of the invention. Like numbered elements in devices 405 and 505 have a similar description with, as given above, and will not be repeated. The device 505 is identical in most aspects to device 405 of FIG. 1 except for the following. Device 505 has an organic stack 516 which includes an EML 520, HT interlayer 418 and HIL/ABL 417.

EML 520

The EML 520 in device 505 is similar in most aspects to EML 420. The description of materials, processes and functions for EML 420 and EML 520 are similar in nature and thus, will not repeated. In contrast to EML 420, however EML 520 also incorporates nanostructures in its fabrication. The nanostructures may include one or more of the following: fullerene (including C60, C70, C76, C78, C82, C84, C90, C96, C140 and so on), soluble fullerene derivatives (including corresponding soluble derivatives of C60, C70, C76, C78, C82, C84, C90, C96, C140 and so on), carbon nanotubes (both single-wall and multi-wall nanotubes). The nanostructures may also include porphyrines, metal filled nanotubes, boron nitride nanotubes, other non-carbon nanotubes or nanostructures and carbon nanotubes doped with boron, nitrogen and so on. Some embodiments of the invention utilize for the nanostructures a soluble derivative of fullerene, namely phenyl-C61-butyric-acid-methyl-ester (PCBM) which is blended with an emissive polymer material to form EML 420. Concentration of nanostructures in the EML should be low enough to prevent emission quenching due to the presence of nanostructures, and should lie in the range between 0 and 1 percent by weight.

Device 505 thus varies from device 405 in that the emissive layer (EML 520) and the HT interlayer 418 both have nanostructures incorporated into them. It is expected that the device 505 has a better operational lifetime performance than device 405. While not shown specifically, any of the layers can also incorporate nanostructures.

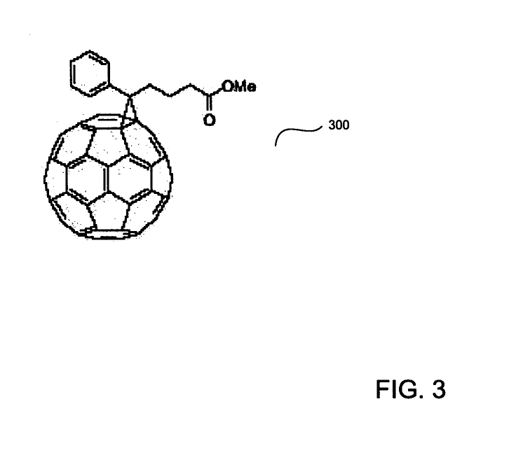

FIG. 3 illustrates an exemplary nanostructure utilized in one or more embodiments of the invention. Nanostructure 300 can be incorporated by blending, chemical bonding, and cross-linking with the functional material (such as the hole transporting polymer or emissive polymer) and/or evaporation with the functional material. The nanostructure 300 is a derivative of fullerene, namely phenyl-C61-butyric-acid-methyl-ester (PCBM), that is soluble in common organic solvents such as toluene, xylene, chlorobenzene and so on. Nanostructures may include Fullerene derivatives which may be used according to the invention in any of the layers of the device include methano-fullerene, bis-methano-fullerene, and tris-methano-fullerene, wherein methano-fullerene is phenyl-Cxx-C-butyric-acid-methyl-ester, and Cxx is a fullerene. Nanostructures used in various embodiments of the invention may also include those fullerenes bridged together, such as when two C60 fullerene units are bridged together utilizing for instance, conjugated oligomers such as a thiopene oligomer, a fluorine oligomer, spiro oligomer, and phenyl-vinylene oligomer or any non-conjugated oligomers.

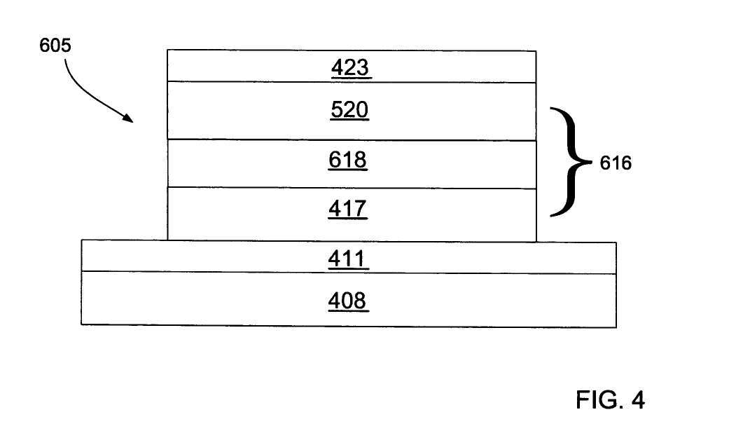

FIG. 4 shows a cross-sectional view of an embodiment of an EL device 605 according to at least a third embodiment of the invention. Like numbered elements in devices 405, 505 and 605 have a similar description with, as given above, and will not be repeated. The device 605 is identical in most aspects to device 505 of FIG. 2 except for the following. Device 605 has an organic stack 616 which includes EML 520, a HT interlayer 618 and HIL/ABL 417.

HT Interlayer 618

The HT interlayer 618 in device 605 is similar in some aspects to HT interlayer 418 of device 405 except for the following. In contrast to HT interlayer 418, HT interlayer 618 does not incorporate any nanostructures in its fabrication. The nanostructures are instead incorporated in EML 520, and optionally in other layers as well, but not in HT interlayer 618. EML 520 has been described with respect to FIG. 2 and will not be repeated.

As any person of ordinary skill in the art of electronic device fabrication will recognize from the description, figures, and examples that modifications and changes can be made to the embodiments of the invention without departing from the scope of the invention defined by the following claims.

1. An electroluminescent device having a plurality of stacked layers, comprising:
an anode layer;
a hole injection/anode buffer layer disposed over said anode layer;
an emissive layer, said emissive layer capable of emitting light; and
a hole transporting interlayer disposed between said hole injection/anode buffer layer and said emissive layer, said interlayer incorporating nanostructures therein.

2. A device according to claim 1 further comprising: a cathode layer disposed above said emissive layer.

3. A device according to claim 1 wherein at least one of said hole injection/anode buffer layer, said emissive layer and said interlayer are formed at least in part using at least one polymer organic material.

4. A device according to claim 1 wherein at least one of said hole injection/anode buffer layer, said emissive layer and said interlayer are formed at least in part using at least one small molecule material.

5. A device according to claim 1 wherein said nanostructures include at least one of: fullerenes, single wall carbon nanotubes, double wall carbon nanotubes, fullerene derivatives, porphorines, metal filled nanotubes, boron nitride, and fullerenes doped with non-carbon materials.

6. A device according to claim 5 wherein said fullerene includes C60, C70, C76, C78, C82, or C84.

7. A device according to claim 5 wherein said fullerene derivative includes at least one of methano-fullerene, bis-methano-fullerene, and tris-methano-fullerene, wherein methano-fullerene is phenyl-Cxx-C-butyric-acid-methyl-ester (PCBM), further wherein Cxx is a fullerene.

8. A device according to claim 1 wherein the concentration of nanostructures in the hole transporting interlayer is from about 0 to 20 percent by weight.

9. A device according to claim 1 wherein said hole transporting interlayer includes materials having at least one of: a polymer, conjugated polymer, a co-polymer, a monomer, a cross-linkable polymer, a polymer blend and a polymer matrix.

10. A device according to claim 9 wherein said conjugated polymer includes a conjugated poly-p-phenylenevinylene polymer.

11. A device according to claim 9 wherein said conjugated polymer includes a conjugated polyspiro polymer.

12. A device according to claim 9 wherein said conjugated polymer includes a conjugated fluorene polymer.

13. A device according to claim 9 wherein said materials and said nanostructures are blended.

14. A device according to claim 9 wherein said materials and said nanostructures form a co-polymer.

15. A device according to claim 9 wherein said materials and said nanostructures are cross-linked.

16. A device according to claim 1 wherein said emissive layer incorporates nanostructures therein.

17. A device according to claim 16 wherein said nanostructures of said emissive layer include at least one of: fullerenes, single wall carbon nanotubes, double wall carbon nanotubes, fullerene derivatives, porphyrines, metal filled nanotubes, boron nitride, and fullerenes doped with non-carbon materials.

18. A device according to claim 17 wherein said fullerene includes C60, C70, C76, C78, C82, or C84.

19. A device according to claim 17 wherein said fullerene derivative includes phenyl-Cxx-C-butyric-acid-methyl-ester (PCBM), where Cxx is a fullerene.

20. A device according to claim 17 wherein the concentration of nanostructures in the emissive layer is 0 to 1 percent by weight.

21. A device according to claim 17 wherein said emissive layer includes materials having at least one of: a polymer, conjugated polymer, a co-polymer, a monomer, a cross-linkable polymer, a polymer blend and a polymer matrix.

22. A device according to claim 21 wherein said conjugated polymer includes a conjugated poly-p-phenylenevinylene polymer.

23. A device according to claim 21 wherein said conjugated polymer includes a conjugated polyspiro polymer.

24. A device according to claim 21 wherein said conjugated polymer includes a conjugated fluorene polymer.

25. A device according to claim 21 wherein said materials and said nanostructures are blended.

26. A device according to claim 21 wherein said materials and said nanostructures form a co-polymer.

27. A device according to claim 21 wherein said materials and said nanostructures are cross-linked.

28. A device according to claim 1 wherein said hole injection/anode buffer layer incorporates nanostructures therein.

29. A device according to claim 28 wherein said nanostructures of said hole injection/anode buffer layer include at least one of: fullerenes, single wall carbon nanotubes, double wall carbon nanotubes, fullerene derivatives, porphyrines, metal filled nanotubes, boron nitride, and fullerenes doped with non-carbon materials.

30. A device according to claim 16 wherein said hole injection/anode buffer layer incorporates nanostructures therein.

31. A device according to claim 30 wherein said nanostructures of said hole injection/anode buffer layer include at least one of: fullerenes, single wall carbon nanotubes, double wall carbon nanotubes, fullerene derivatives, porphyrines, metal filled nanotubes, boron nitride, and fullerenes doped with non-carbon materials.

32. An electroluminescent device having a plurality of stacked layers, comprising:
an anode layer; a hole injection/anode buffer layer disposed over said anode layer; an emissive layer, said emissive layer capable of emitting light, said emissive layer incorporating nanostructures therein; and a hole transporting interlayer disposed between said hole injection/anode buffer layer and said emissive layer.

33. A device according to claim 32 further comprising:
a cathode layer disposed above said emissive layer.

34. A device according to claim 32 wherein at least one of said hole injection/anode buffer layer, said emissive layer and said interlayer are formed at least in part using at least one polymer organic material.

35. A device according to claim 32 wherein at least one of said hole injection/anode buffer layer, said emissive layer and said interlayer are formed at least in part using at least one small molecule material.

36. A device according to claim 32 wherein said nanostructures include at least one of: fullerenes, single wall carbon nanotubes, double wall carbon nanotubes, fullerene derivatives, porphyrines, metal filled nanotubes, boron nitride, and fullerenes doped with non-carbon materials.

37. A device according to claim 36 wherein said fullerene includes C60, C70, C76, C78, C82, or C84.

38. A device according to claim 37 wherein said fullerene derivative includes at least one of methano-fullerene, bis-methano-fullerene, and tris-methano-fullerene, wherein methano-fullerene is phenyl-Cxx-C-butyric-acid-methyl-ester (PCBM), further wherein Cxx is a fullerene.

39. A device according to claim 36 wherein the concentration of nanostructures in the emissive layer is 0 to 1 percent by weight.

40. A device according to claim 32 wherein said emissive layer includes materials having at least one of: a polymer, conjugated polymer, a co-polymer, a monomer, a cross-linkable polymer, a polymer blend and a polymer matrix.

41. A device according to claim 40 wherein said conjugated polymer includes a conjugated poly-p-phenylenevinylene polymer.

42. A device according to claim 40 wherein said conjugated polymer includes a conjugated polyspiro polymer.

43. A device according to claim 40 wherein said conjugated polymer includes a conjugated fluorene polymer.

44. A device according to claim 40 wherein said materials and said nanostructures are blended.

45. A device according to claim 40 wherein said materials and said nanostructures form a co-polymer.

46. A device according to claim 40 wherein said materials and said nanostructures are cross-linked.

47. A device according to claim 4 wherein said small molecule material includes at least one of: fluorocarbon, copper phthalocyanine, triphenyldiamineα-napthylphenyl-biphenyl, tris(8-hydroxyquinolate) aluminum, anthracene, rubrene, tris(2-phenylpyridine) iridium, triazine, any metal-chelate compounds and derivatives of any of these materials.

48. A device according to claim 35 wherein said small molecule material includes at least one of: fluorocarbon, copper phthalocyanine, triphenyldiamineα-napthylphenyl-biphenyl, tris(8-hydroxyquinolate) aluminum, anthracene, rubrene, tris(2-phenylpyridine) iridium, triazine, any metal-chelate compounds and derivatives of any of these materials.

49. A device according to claim 5 wherein said fullerene includes at least two fullerene units bridged together.

50. A device according to claim 37 wherein said fullerene includes at least two fullerene units bridged together.

51. A device according to claim 49 wherein said at least two fullerene units includes two C60 units.

52. A device according to claim 50 wherein said at least two fullerene units includes two C60 units.
